(19) United States
(12) Patent Application Publication
(10) Pub. No.: US 2025/0102017 A1
(43) Pub. Date: Mar. 27, 2025

(54) PROCESS FOR DETERMINING THE RELIABILITY OF A SENSORIZED ROLLER BEARING

(71) Applicant: Aktiebolaget SKF, Göteborg (SE)

(72) Inventors: Andreas Clemens van der Ham, Utrecht (NL); Alireza Azarfar, Utrecht (NL); Dominik Fritz, Würzburg (DE); Stefan Engbers, Wuerzburg (DE); Juergen Reichert, Donnersdorf (DE); Defeng Lang, Delft (NL)

(21) Appl. No.: 18/974,199

(22) Filed: Dec. 9, 2024

Related U.S. Application Data
(63) Continuation-in-part of application No. 17/708,324, filed on Mar. 30, 2022.

(30) Foreign Application Priority Data
Apr. 7, 2021 (DE) 102021203446.2

(51) Int. Cl. F16C 41/00; F03D 17/00; G01R 31/00

(52) U.S. Cl. CPC F16C 41/00; F03D 17/032; G01R 31/003; F16C 2233/00; F16C 2360/31

(57) ABSTRACT

A process for determining the reliability of a sensorized bearing configured to measure load and speed is provided. The process includes the following steps. Bearing load and rotational speed are determined from data acquired from the sensorized bearing. Next, an array linking the determined load to the determined n·dm value is filled until that all available loads are parsed. Then a L10 life is determined for each load within a distribution based on the array. Finally, an overall L10 life is determined based on the Palmgren-Miner rule. The load distribution and the L10 lives a bearing reliability R for a given date is determined based on a Weibull curve and the overall L10 life. The process may be carried out by a computer having a processor and a memory.

### CROSS-REFERENCE TO RELATED APPLICATIONS

This application claims priority to U.S. patent application Ser. No. 17/708,324, filed Mar. 30, 2022, which claims priority to German Patent Application no. 102021203446.2, filed Apr. 7, 2021, the contents of each of which are fully incorporated herein by reference.

### TECHNICAL FIELD OF THE INVENTION

The present invention relates to sensorized roller bearings, and in particular to such bearings supporting a wind turbine main shaft.

### BACKGROUND OF THE INVENTION

Bearings are often specified to have an “L10” life for an application. This is the duration after which ten percent of the bearings in that application can be expected to have failed due to classical fatigue failure (and not any other mode of failure like lubrication starvation, wrong mounting etc.). In other words, it is the duration at which ninety percent of the bearings will still be operating. The L10 life of the bearing is its theoretical life and may not represent the service life of the bearing during operation.

The L10 bearing life is calculated using a repartition or histogram of loads that are planned to be applied to the bearing according to customer specifications.

An L10ᵢ value is then determined for each load case (bin of the histogram). In order to do so, the frequency for a given load case is converted into a duty cycle.

$$L {10}_{i} = {( \frac{C}{P} )}^{p}$$

Where:
L10ᵢ: the basic rating life at 90% probability in millions of revolutions
C: the dynamic load rating in kN
P: the equivalent dynamic bearing load in kN
p: a geometrical constant (3 for ball bearings, 10/3 for roller bearings)

The L10; life in millions of revolutions can be converted to L10hᵢ life in operating hours through the following formula:

$$L 10 {h}_{i} = \frac{1 {0}^{6}}{60 \cdot n} L {10}_{i}$$

Where:
n: rotational speed

Based on that duty cycle and the Palmgren-Miner rule, the overall L10 life is calculated.

$$L 10 h = \sqrt{{Σ}_{i} \frac{L 10 {{h}_{i}}^{2}}{{d}_{i}}}$$

Where
i: index for each load case
dᵢ: duty cycle (percentage of occurrence of load case)

Based on the overall L10h life, the Weibull probability density function, or reliability R which is the probability that the bearing will survive after a duration of operation given the overall L10h life, can then be determined based on the following equation:

$$R = {e}^{- {( \frac{t}{c . L 10 h} )}^{k}}$$

$$c = 1 / \sqrt[k]{- ln ( 0.9 )}$$

Where:
k is a constant shape parameter,
L10h is the overall L10h life,
c is a correction factor
t is the time elapsed since bearing installation (hours)

However, client specifications can be either optimistic or quite different from actual operation data. The overall L10 life and the reliability R determined based on client specification can then differ by significant amounts from the corresponding values determined based on actual operation data. Those differences, in turn, translate into different operation margins and profitability, essentially due to missed income if the client specifications are too conservative, or premature servicing and maintenance if the client specifications are too optimistic. In a wind turbine, the replacement of a main shaft bearing may cost 3 M€, while the bearing itself only costs 300 k€. It is therefore quite important to have the right bearing for the actual operation.

There is a need for a real time determination of both overall L10 life and reliability in order for the operation parameters to be adjusted after operation has started.

In order to estimate the state of a bearing, several methods are known.

Taking samples of the lubricant is a way to keep track of the bearing condition. This requires climbing the wind turbine tower and is therefore not done very often.

The clearance between the bearing rings can be measured as a measure for the state of the bearing. A loss of preload or wear may be a reason for a change in clearance and so gives an indication of a change in the state of the bearing. However, it also means accessing the turbine at the top of the wind turbine tower, which is rarely performed, especially for off-shore wind turbines.

None of those methods allows either for easy or real-time monitoring of the bearing in order to determine its reliability.

None of those methods allows for adjusting the operating parameters of a wind turbine based on the main shaft bearing reliability.

### SUMMARY OF THE INVENTION

An object of the invention is a process for determining the reliability of a sensorized roller bearing provided with an inner ring, with an outer ring and with at least one row of rollers comprising at least one sensorized roller, the at least one sensorized roller being configured to measure at least load and speed, the process comprising the following steps:
bearing temperature, load and rotational speed are determined from data acquired from the at least one sensorized roller,
a n·dm value is determined as being equal to the rotation speed times the mean diameter of the roller bearing,
an entry is filed in an array, linking the determined load to the determined n·dm value, the n·dm values are aggregated over all the measurements,
those steps are performed in a loop until that all available loads are parsed resulting in a load distribution, then the process resumes with the following steps:
a distribution linking the percentage of occurrences versus each load is calculated based on the array, then a L10 life is determined for each load within the distribution, and an overall L10 life is determined based on the Palmgren-Miner rule, the load distribution and the L10 lives, and
a bearing reliability R for a given date is determined based on the Weibull curve and the overall L10 life.

In an embodiment, the sensorized roller bearing comprises at least first and second rows of rollers, each row comprising at least one sensorized roller, bearing load and rotational speed being determined from data acquired from the sensorized rollers of the first and second rows.

The date for determining the reliability can be any point of time, past, present or future.

The bearing temperature can be determined from data acquired from the at least one sensorized roller.

Another object of the invention is a process for controlling a wind turbine having a main shaft supported by at least one sensorized roller bearing, wherein the operating parameters of the wind turbine are adjusted based on the L10 life and the reliability as determined above.

The reliability can be determined for several dates in the future, the reliability for each date is then compared to a threshold and maintenance is planned for the first date associated with a reliability lower than the threshold.

The process is advantageous in that it provides a direct feedback of the bearing usage and the consequences of that usage. It also enables a periodic or real time monitoring.

This can be used for supervisory control of the wind turbine and also help in deciding which turbines to shut down when the energy need is low.

### BRIEF DESCRIPTION OF THE DRAWING

At least one of the embodiments of the present invention is accurately represented by this application's drawings which are relied on to illustrate such embodiment(s) to scale and the drawings are relied on to illustrate the relative size, proportions, and positioning of the individual components of the present invention accurately relative to each other and relative to the overall embodiment(s). Those of ordinary skill in the art will appreciate from this disclosure that the present invention is not limited to the scaled drawings and that the illustrated proportions, scale, and relative positioning can be varied without departing from the scope of the present invention as set forth in the broadest descriptions set forth in any portion of the originally filed specification and/or drawings. The present invention will be better understood from studying the detailed description of a number of embodiments considered by way of entirely non-limiting examples and illustrated by the attached drawing in which:

FIG. 1 shows the main components of a sensorized bearing,

FIG. 2 shows the main steps of a process according to the invention,

FIG. 3 shows the geometric relationship between the forces applied to the rollers and the forces applied on the bearing,

FIG. 4 shows the main steps of a process according to an alternative preferred embodiment of the present invention,

FIG. 5 shows the sensorized bearing connected with the computer that carries out the process, and

FIG. 6 shows schematically the entire system including the sensorized bearing and the computer that carries out the process as described.

### DETAILED DESCRIPTION OF THE INVENTION

Those of ordinary skill in the art will appreciate from this disclosure that when a range is provided such as (for example) an angle/distance/number/weight/volume/spacing being between one (1 of the appropriate unit) and ten (10 of the appropriate units) that specific support is provided by the specification to identify any number within the range as being disclosed for use with a preferred embodiment. For example, the recitation of a percentage of copper between one percent (1%) and twenty percent (20%) provides specific support for a preferred embodiment having two point three percent (2.3%) copper even if not separately listed herein and thus provides support for claiming a preferred embodiment having two point three percent (2.3%) copper. By way of an additional example, a recitation in the claims and/or in portions of an element moving along an arcuate path by at least twenty (20°) degrees, provides specific literal support for any angle greater than twenty (20°) degrees, such as twenty-three (23°) degrees, thirty (30°) degrees, thirty-three-point five (33.5°) degrees, forty-five (45°) degrees, fifty-two (52°) degrees, or the like and thus provides support for claiming a preferred embodiment with the element moving along the arcuate path thirty-three-point five (33.5°) degrees. In order to solve the aforementioned drawbacks, the inventors got the idea to use the data provided by a sensorized bearing in order to estimate the bearing reliability. Documents DE201810200047, DE201610211779 and DE201810200048 disclose different examples of such a sensorized bearing. In particular, the determination of a bearing reliability can be applied to a wind turbine where the main shaft bearing is a sensorized bearing.

Thanks to the data available through the sensorized bearing, the load frequency can be updated and a new overall L10 life can be calculated.

Based on the overall L10 life and the turbine operation duration, the current reliability of the main shaft bearing can be calculated using the Weibull curve.

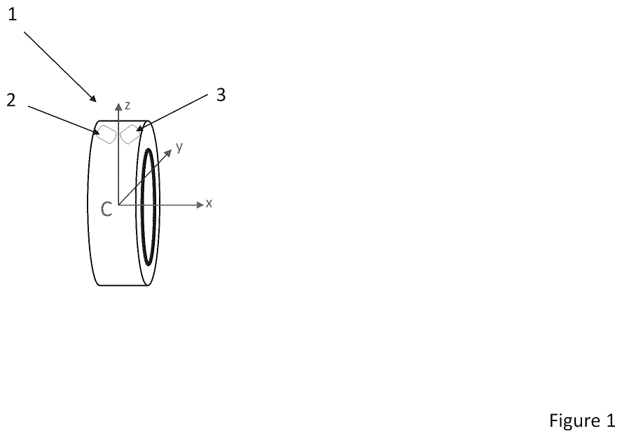

FIG. 1 illustrates a sensorized bearing 1, similar to a conventional bearing and of a roller bearing type. The sensorized bearing 1 comprises an inner ring, an outer ring, first and second row of rollers arranged between raceways provided on the inner and outer rings. The rollers may be tapered, spherical or cylindrical rollers.

The sensorized bearing differs from a conventional bearing in that one roller 2 in the first row and one roller 3 in the second row are each embedded with sensors for determining forces Fr1 and Fr2 applied respectively on their surface along with their rotation speed and, eventually temperature. In the illustrated example, the sensorized roller 2 axially faces the sensorized roller 3.

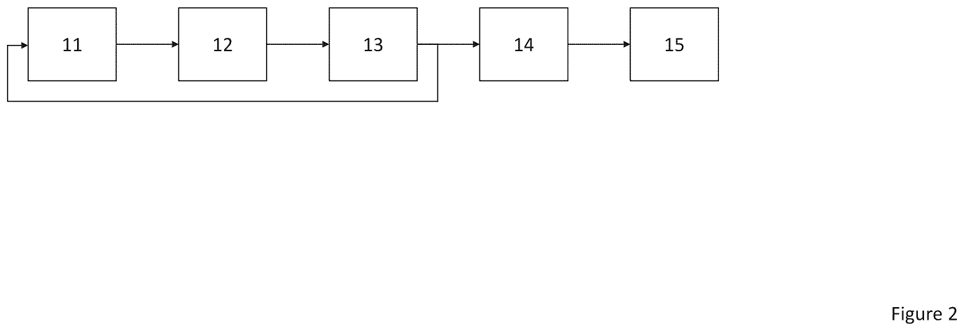

A process for determining the reliability of the sensorized bearing is illustrated by FIG. 2.

During a first step 11, bearing temperature, load and rotational speed are determined out of data acquired from the sensorized rollers.

Bearing temperature is determined based on a model out of the sensorized rollers measured temperature and the geometry of the bearing.

Similarly, bearing rotational speed is determined based on a model out of the sensorized rollers measured rotational speed and the geometry of the bearing.

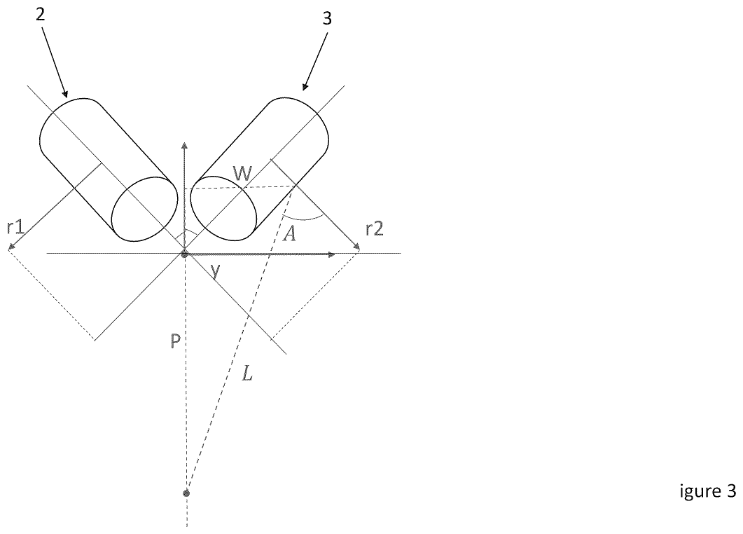

Radial and axial bearing loads are determined first by projecting roller forces onto the radial and axial directions. FIG. 3 illustrates the position of the sensorized roller 2 and the position of the sensorized roller 3 in respect to bearing center C along with the applied forces Fr1, Fr2 and the resulting loads Fx, Fy, Fz in an orthonormal frame.

Based on the measured roller forces Fr1 and Fr2 in the two raceways, the axial load Fx can be determined based on the following equation:

$$F x = ( Fr 2 - Fr 1 ) * cos ( ϵ )$$

where ϵ is π/2—the contact angle of the roller to the raceway.

Two radial loads Fy, Fz can be determined based on the following equations:

$$F y = ( Fr 1 + Fr 2 ) * sin ( ϵ ) * sin ( θ )$$

$$Fz = ( Fr 1 + Fr 2 ) * sin ( ϵ ) * cos ( θ )$$

where θ is the angle of the roller around the circumference of the bearing.

In the present invention, θ is chosen equal to 0 so that the radial load considered is the vertical load comprised in a plane extending in between the sensorized rollers.

In order to determine the moments Mx and My, the distance L between the applied load locus and the bearing center of rotation and the angle A between the applied load direction and the direction extending between the applied load locus and the bearing center of rotation are determined thanks to the following equations:

$$A = ϵ - a tan ( W / P )$$

$$L = \sqrt{{P}^{2} + {W}^{2}}$$

Where:
W is the width from center of the bearing to the roller
P is the pitch radius

The moments Mx and My are determined by applying the following equations:

$$M x = ( Fr 2 - Fr 1 ) * cos ( A ) * L * cos ( θ )$$

$$My = ( Fr 2 - Fr 1 ) * cos ( A ) * L * sin ( θ )$$

It is reminded that θ is chosen equal to 0. My is then equal to 0.

Once the radial and axial forces and moment are determined for the pair of sensorized rollers, the corresponding values for the bearing can be determined through integration or summation on a full ring of rollers.

During a second step 12, the n·dm value is determined as being equal to the rotation speed times the mean diameter of the bearing.

During a third step 13, an entry is filed in an array, linking the current loads to the n·dm value.

Steps 11 to 13 are performed in a loop so that all available loads are parsed.

During a fourth step 14, a distribution linking the percentage of occurrences versus each load is calculated based on the array. A L10 life is determined for each load within the distribution. The overall L10 life is then determined based on the Palmgren-Miner rule and the load distribution.

During a fifth step 15, the reliability R for a given date is determined based on the Weibull curve and the overall L10 life. The instant can be any point of time, past, present or future.

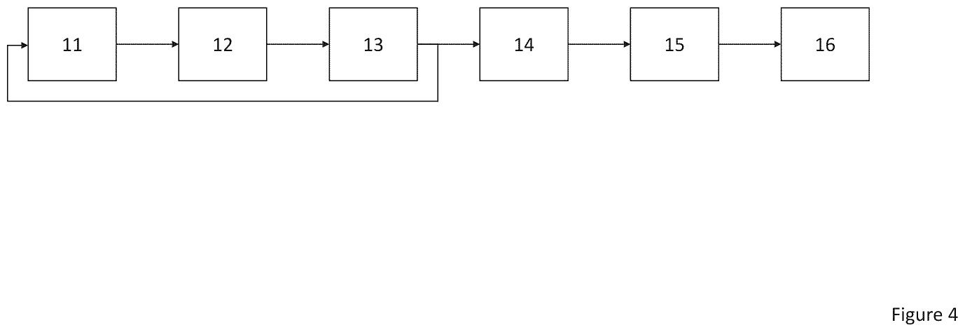

A process for controlling a wind turbine in order to optimize the main shaft bearing life and operation of the wind turbine comprises the following steps and is illustrated by the FIG. 4.

Steps 11 to 15 are similar to those described above in relation with the process for determining the reliability of a sensorized bearing. After the fifth step 15, the present process continues with a sixth step 16, during which the operating parameters of the wind turbine are adjusted based on the L10 life and the current reliability.

Alternatively, during the sixth step 16, the reliability is determined for several dates in the future. The reliability for each date is then compared to a threshold and maintenance is planned for the first date associated with a reliability lower than the threshold.

In a particular embodiment, only one sensorized roller is present or considered for determination of the loads, rotational speed and temperature. Depending of the sensorized roller present or active, load Fr1 or Fr2 are considered equal to zero in the aforementioned equations. In another embodiment, the rolling bearing comprises only one single row of rollers with at least one sensorized roller.

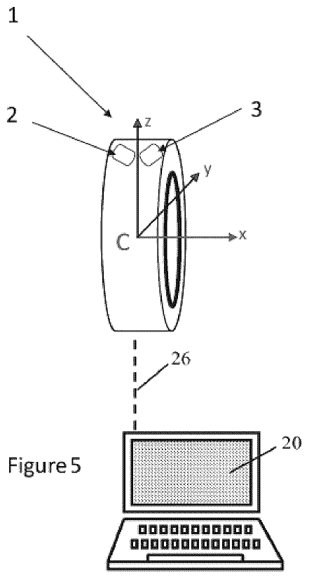

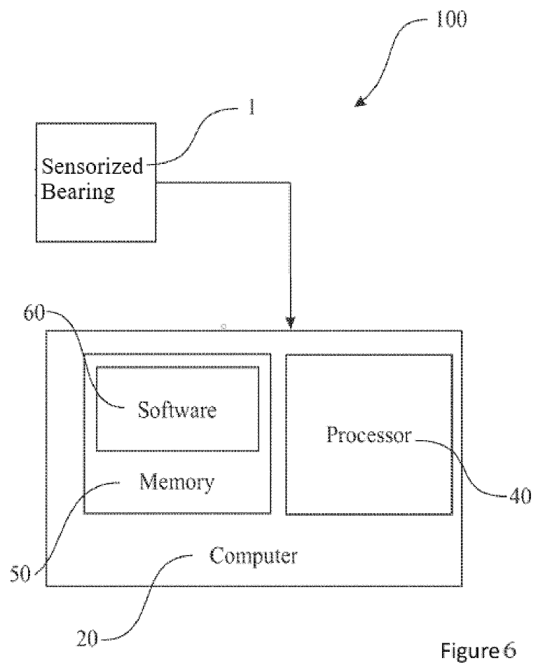

FIG. 5 may show the sensorized bearing 1 connected to a computer 20. The sensorized rollers 2, 3, after collecting data as described in the first step 11 above, may transmit the data to the computer 20 via a wireless connection 26. One of ordinary skill in the art will appreciate from this disclosure that the wireless connection 26 may be wired, RFID, Bluetooth, Ethernet, Wi-Fi, or the like, without departing from the scope of the present invention. The computer 20 may then carry out steps 12 to 16 as described above and as described in more detail in relation to FIG. 6 below.

FIG. 6 may show a system 100 for carrying out the aforementioned processes as described in steps 11 to 16. The system 100 may comprise a sensorized bearing 1 connected to a computer 20. The computer may comprise a processor 40 and a memory 50. The memory 50 may store a software 60. The steps 12 and 13 may be carried out by the processor 40. The arrays generated by step 13 may be stored in the memory 50. Individual L10 lives and individual reliabilities R for given dates may also be stored in the memory 50 during steps 14 and 15. These may then be accessed by the processor 40 during any of the steps 11 to 16 for calculating any of the parameters mentioned above in connection with steps 11 to 16. Optionally, a software 60 stored in the memory 50 may be configured to automatically carry out the process in whole or in part.

What is claimed is:

1. A process for determining the reliability of a sensorized roller bearing, the process comprising the following steps:
providing the sensorized roller bearing having an inner ring, an outer ring and at least one row of rollers, the at least one row of rollers comprising at least one sensorized roller, the at least one sensorized roller being configured to measure at least bearing load and rotational speed of the sensorized roller bearing, and
providing a computer having a processor and a memory, the processor being configured to carry out the following steps:
acquiring the bearing load and the rotational speed from the at least one sensorized roller,
determining a n·dm value as being equal to the rotation speed times the mean diameter of the sensorized roller bearing,
filing an entry in an array,
linking the bearing load to the n·dm value,
performing those steps in a loop so that the n·dm values are aggregated over all the measurements and all bearing loads are parsed resulting in a bearing load distribution, then the process resumes with the following steps:
calculating a distribution linking a percentage of occurrences versus each load based on the array,
determining a L10 life for each bearing load within the bearing load distribution,
calculating an overall L10 life based on the Palmgren-Miner rule, the bearing load distribution and the L10 life for each bearing load, and
determining a bearing reliability R for a given date based on a Weibull curve and the overall L10 life.

2. The process according to claim 1, wherein the sensorized roller bearing comprises at least first and second rows of rollers, each row comprising at least one sensorized roller, bearing load and rotational speed being determined from data acquired from the sensorized rollers of the first and second rows.

3. The process according to claim 1, wherein the date for determining the reliability is any point of time, past, present or future.

4. The process according to claim 1, wherein bearing temperature is determined from data acquired from the at least one sensorized roller.

5. The process according to claim 1, wherein the memory is configured to store a software.

6. The process according to claim 5, wherein the software is configured to automatically trigger the processor to carry out any of the steps of the process.

7. The process according to claim 1, wherein the memory is configured to store any of the following: the bearing load, the rotational speed, the n·dm value, the entry, the array, the distribution, the percentage of occurrences, the L10 life, the overall L10 life, and the bearing reliability R.

8. A process for controlling a wind turbine, the operating parameters of the wind turbine being adjusted based on a L10 life and determined reliability R of a sensorized roller bearing, the process comprising the following steps:
providing the wind turbine having a main shaft supported by at least one sensorized roller bearing, the sensorized roller bearing having an inner ring, an outer ring and at least one row of rollers, the at least one row of rollers comprising at least one sensorized roller, the at least one sensorized roller being configured to measure at least bearing load and rotational speed of the sensorized roller bearing, and
providing a computer having a processor and a memory, the processor being configured to carry out the following steps:
acquiring the bearing load, the rotational speed, and the temperature data from the at least one sensorized roller,
determining a n·dm value as being equal to the rotation speed times the mean diameter of the sensorized roller bearing,
filing an entry in an array,
linking the bearing load to the n·dm value,
performing those steps in a loop so that the n·dm values are aggregated over all the measurements and all bearing loads are parsed resulting in a bearing load distribution, then the process resumes with the following steps:
calculating a distribution linking a percentage of occurrences versus each load based on the array,
determining a L10 life for each bearing load within the bearing load distribution,
calculating an overall L10 life based on the Palmgren-Miner rule, the bearing load distribution and the L10 life for each bearing load, and
determining a bearing reliability R for a given date based on a Weibull curve and the overall L10 life.

9. The process according to claim 8, wherein the reliability is determined for several dates in the future, the reliability for each date is then compared to a threshold and maintenance is planned for the first date associated with a reliability lower than the threshold.

10. The process according to claim 8, wherein the sensorized roller bearing comprises at least first and second rows of rollers, each row comprising at least one sensorized roller, bearing load and rotational speed being determined from data acquired from the sensorized rollers of the first and second rows.

11. The process according to claim 8, wherein bearing temperature is determined from data acquired from the at least one sensorized roller.

12. The process according to claim 8, wherein the memory is configured to store a software.

13. The process according to claim 12, wherein the software is configured to automatically trigger the processor to carry out any of the steps of the process.

14. The process according to claim 8, wherein the memory is configured to store any of the following: the bearing load, the rotational speed, the n·dm value, the entry, the array, the distribution, the percentage of occurrences, the L10 life, the overall L10 life, and the bearing reliability R.

15. A system for determining the reliability of a sensorized roller bearing, the system comprising:
the sensorized roller bearing having an inner ring, an outer ring and at least one row of rollers, the at least one row of rollers comprising at least one sensorized roller, the at least one sensorized roller being configured to measure at least bearing load and rotational speed of the sensorized roller bearing, and
a computer having a processor and a memory, the processor being configured to carry out the following steps to determine the reliability of the sensorized roller bearing:
acquiring the bearing load and the rotational speed from the at least one sensorized roller,
determining a n·dm value as being equal to the rotation speed times the mean diameter of the sensorized roller bearing,
filing an entry in an array,
linking the bearing load to the n·dm value,
performing those steps in a loop so that the n·dm values are aggregated over all the measurements and all bearing loads are parsed resulting in a bearing load distribution, then the process resumes with the following steps:
calculating a distribution linking a percentage of occurrences versus each load based on the array,
determining a L10 life for each bearing load within the bearing load distribution,
calculating an overall L10 life based on the Palmgren-Miner rule, the bearing load distribution and the L10 life for each bearing load, and
determining a bearing reliability R for a given date based on a Weibull curve and the overall L10 life.

16. The system according to claim 15, wherein the sensorized roller bearing comprises at least first and second rows of rollers, each row comprising at least one sensorized roller, bearing load and rotational speed being determined from data acquired from the sensorized rollers of the first and second rows.

17. The system according to claim 15, wherein bearing temperature is determined from data acquired from the at least one sensorized roller.

18. The system according to claim 15, wherein the memory is configured to store a software.

19. The system according to claim 18, wherein the software is configured to automatically trigger the processor to carry out any of the steps to determine the reliability of the sensorized roller bearing.

20. The system according to claim 8, wherein the memory is configured to store any of the following: the bearing load, the rotational speed, the n·dm value, the entry, the array, the distribution, the percentage of occurrences, the L10 life, the overall L10 life, and the bearing reliability R.
